(19) United States
(12) Patent Application Publication
(10) Pub. No.: US 2026/0040899 A1
(43) Pub. Date: Feb. 5, 2026

(54) SILICON INTERPOSER WITH INTEGRATED FINE-PITCH WAFER TEST PROBES

(71) Applicant: International Business Machines Corporation, Armonk, NY (US)

(72) Inventors: David Michael Audette, Colchester, VT (US); Christopher Michael Fieldsend, Williston, VT (US); Grant Wagner, Jericho, VT (US); Melissa Keefe, Cortlandt Manor, NY (US); Peter William Neff, Cambridge, VT (US)

(21) Appl. No.: 18/789,891

(22) Filed: Jul. 31, 2024

(51) Int. Cl. H01L 21/66; H01L 21/288; H01L 23/498

(52) U.S. Cl. CPC H01L 22/32; H01L 21/288; H01L 22/34; H01L 23/49827; H01L 23/49838

(57) ABSTRACT

A wafer test probe includes a pillar, a conductive line isolated from and extending through the pillar, a probe tip forming an opening, and a first conductive coating isolated from the pillar to coat the probe tip at least at the opening. The probe time includes blade features disposed in electrical contact with the conductive line via the first conductive coating. The blade features terminate at the opening and are configured to conductively penetrate a solder bump. A second conductive coating is disposed over the first conductive coating to coat the blade features.

### BACKGROUND

The present disclosure generally relates to fabrication methods and resulting structures for semiconductor devices. More specifically, the present disclosure relates to a silicon interposer with or without a laminate or a fine-pitch laminate with integrated fine-pitch wafer test probes.

Wafer testing is performed during semiconductor device fabrication and generally after back-end-of-line (BEOL) processing. During wafer testing, individual integrated circuits (ICs) that are present on the wafer are tested for functional defects by applying special test patterns to them. The wafer testing is performed by a piece of test equipment called a tester, along with a wafer prober, electrically connected to the wafer via the wafer probe.

### SUMMARY

According to a non-limiting embodiment, a wafer test probe includes a pillar, a conductive line isolated from and extending through the pillar, a probe tip forming an opening, and a first conductive coating isolated from the pillar to coat the probe tip at least at the opening. The probe time includes blade features disposed in electrical contact with the conductive line via the first conductive coating. The blade features terminate at the opening and are configured to conductively penetrate a solder bump. A second conductive coating is disposed over the first conductive coating to coat the blade features. Accordingly, a wafer test probe is provided to include small, sharp and relatively tall (i.e., high aspect ratio) features for fine pitch testing.

In addition to one or more of the features described above, or as an alternative to any of the foregoing embodiments, the pillar is a semiconductor pillar and the conductive line is a through silicon via (TSV) surrounded by electrically isolating dielectric material.

In addition to one or more of the features described above, or as an alternative to any of the foregoing embodiments, the conductive line is provided as first and second conductive lines at opposite sides of the opening.

In addition to one or more of the features described above, or as an alternative to any of the foregoing embodiments, the first conductive coating comprises a first metallic material, and the second conductive coating comprises a second metallic material, which differs from the first metallic material, which resists oxidation and which is chemically cleanable.

In addition to one or more of the features described above, or as an alternative to any of the foregoing embodiments, the blade features have a dog-bone shape, which cannot be achieved using current copper electroplating processes.

In addition to one or more of the features described above, or as an alternative to any of the foregoing embodiments, the blade features are opposed polyhedron tips.

In addition to one or more of the features described above, or as an alternative to any of the foregoing embodiments, the blade features are inward blades arranged at uniform angular intervals.

According to another non-limiting embodiment, a wafer test probe assembly comprises a probe card, at least one of a silicon interposer, a fine-pitch organic substrate, a fine-pitch organic substrate with a silicon interposer, and a pogo interposer interposed between the probe card and the at least one of the silicon interposer, the fine-pitch organic substrate and the fine-pitch organic substrate with the silicon interposer. The wafer test probe assembly further includes fine-pitch wafer test probes according to a wafer test probe of claim described herein, which are arranged on a surface of the at least one of the silicon interposer, the fine-pitch organic substrate and the fine-pitch organic substrate with the silicon interposer. Accordingly, a wafer test probe is provided to include small, sharp and relatively tall (i.e., high aspect ratio) features for fine pitch testing.

According to a non-limiting embodiment, a wafer test probe comprises a semiconductor pillar, a conductive line isolated from and extending through the semiconductor pillar, and layers disposed on the semiconductor pillar to form a layer body with an exterior surface and an opening extending into the layer body from the exterior surface. Each of the layers comprising dielectric material and conductive material, the conductive material forming an additional conductive line in electrical contact with the conductive line and extending through the layer body. Blade features are disposed on the exterior surface of the layer body in electrical contact with the additional conductive line. The blade features comprise terminal ends that terminate at the opening and that are configured to conductively penetrate into a solder bump. A conductive coating is disposed on the blade features and the terminal ends thereof.

In addition to one or more of the features described above, or as an alternative to any of the foregoing embodiments, the conductive line is a through silicon via (TSV) surrounded by electrically isolating dielectric material.

In addition to one or more of the features described above, or as an alternative to any of the foregoing embodiments, the conductive line is provided as first and second conductive lines at opposite sides of the opening.

In addition to one or more of the features described above, or as an alternative to any of the foregoing embodiments, the blade features comprise a first metallic material, and the conductive coating comprises a second metallic material, which differs from the first metallic material, which resists oxidation and which is chemically cleanable.

In addition to one or more of the features described above, or as an alternative to any of the foregoing embodiments, the blade features have a dog-bone shape, which cannot be achieved using current copper electroplating processes.

In addition to one or more of the features described above, or as an alternative to any of the foregoing embodiments, the blade features are opposed polyhedron tips.

In addition to one or more of the features described above, or as an alternative to any of the foregoing embodiments, the blade features are inward blades arranged at uniform angular intervals.

According to another non-limiting embodiment, a method of fabricating a wafer test probe comprises etching an opening into a semiconductor pillar to expose a material of one or more conductive lines electrically isolated from the semiconductor pillar, and patterning the etching such that the etching forms, in a remainder of the semiconductor pillar, blade features electrically isolated from the semiconductor pillar and terminating at the opening. The method further comprises plating the blade features and the material of the one or more conductive lines with a first conductive material, and plating the first conductive material with a second conductive material, which differs from the first metallic material, which resists oxidation and which is chemically cleanable. Accordingly, a method is provided to fabricate a wafer test probe that is formed by an etching process to include small, sharp and relatively tall (i.e., high aspect ratio) features for fine pitch testing.

In addition to one or more of the features described above, or as an alternative to any of the foregoing embodiments, the patterning comprises forming the blade features to have a dog-bone shape, which cannot be resolved using current copper electroplating processes.

In addition to one or more of the features described above, or as an alternative to any of the foregoing embodiments, the patterning comprises forming the blade features to be opposed polyhedron tips.

In addition to one or more of the features described above, or as an alternative to any of the foregoing embodiments, the patterning comprises forming the blade features to be arranged at uniform angular intervals.

According to yet another non-limiting embodiment, a method of fabricating a wafer test probe comprises forming a semiconductor pillar with one or more conductive lines extending through the semiconductor pillar with electrical isolation, etching an opening into an end of the semiconductor pillar to expose a material of the one or more conductive lines, and patterning the etching such that the etching forms, in a remainder of the end of the semiconductor pillar, blade features electrically isolated from the semiconductor pillar and terminating at the opening. The method further includes plating the blade features and the material of the conductive line with a first conductive material, and plating the first conductive material with a second conductive material, which differs from the first metallic material, which resists oxidation and which is chemically cleanable. Accordingly, a method is provided to fabricate a wafer test probe that is formed by an etching process to include small, sharp and relatively tall (i.e., high aspect ratio) features for fine pitch testing.

According to still another non-limiting embodiment, a method of fabricating a wafer test probe comprises forming a semiconductor pillar with one or more electrically isolated conductive lines, and building up a layer body on the semiconductor pillar with layers comprising dielectric material and conductive material such that the conductive material forms an additional conductive line electrically contacting the conductive line and extending through the layer body. The method further comprises disposing blade features configured to conductively penetrate into a solder bump on the layer body in electrical contact with the additional conductive line, etching an opening into the blade features and the layer body, and disposing a conductive coating on at least the blade features. Accordingly, a method is provided to fabricate a wafer test probe that is formed by an etching process to include small, sharp and relatively tall (i.e., high aspect ratio) features for fine pitch testing.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a side view of a wafer test probe with a single conductive line extending through a semiconductor pillar in accordance with one or more embodiments;

FIG. 2 is a side view of a wafer test probe with multiple conductive lines extending through a semiconductor pillar in accordance with one or more embodiments;

FIG. 3 is a perspective view of dog-bone shaped blade features of the wafer test probes of FIGS. 1 and 2 in accordance with one or more embodiments;

FIG. 4 is a perspective view of opposed polyhedron tips of blade features of the wafer test probes of FIGS. 1 and 2 in accordance with one or more embodiments;

FIG. 5 is a perspective view of inward facing blades of blade features of the wafer test probes of FIGS. 1 and 2 in accordance with one or more embodiments;

FIG. 6A is a side view of a wafer test probe assembly in accordance with one or more embodiments;

FIG. 6B is a cross-sectional view taken along line 6B-6B of FIG. 6A and illustrating wafer test probes of the wafer test probe assembly of FIG. 6A in accordance with one or more embodiments;

FIG. 7A is a side view of a wafer test probe including an etched layer body in accordance with one or more embodiments;

FIG. 7B is a top-down view of the wafer test probe of FIG. 7A in accordance with one or more embodiments;

FIG. 8 is a flow diagram illustrating a method of fabricating a wafer test probe in accordance with one or more embodiments;

FIG. 9 is a flow diagram graphically illustrating the method of FIG. 8 in accordance with one or more embodiments;

FIG. 10 is a flow diagram illustrating a method of fabricating a wafer test probe using etching processes in accordance with one or more embodiments; and

FIG. 11 is a flow diagram illustrating a method of fabricating a wafer test probe with a layer body using etching processes in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, current industry standard (cobra, vertical MEMs) wafer test probes are often challenged with scale and cost. As chip bump size and pad pitch shrink, it becomes increasingly difficult to manufacture all components of the wafer test probe including probe pins, their housings and the probe layer that electrically connects them to the probe card. This difficulty drives high costs.

To avoid the high cost of industry standard probes, wafer test probes using a rigid pin concept have been proposed. These concepts use photolithography to build up the main structure or body of the probe pins out of copper, which is then plated with a thin nickel-gold (NiAu) coating to prevent oxidation of the copper. This probe technology can be an order of magnitude cheaper than industry standard probes, but has limitations in scale due to the photoresists used in the fabrication process. The feature resolution is limited by the aspect ratio of the probe features relative to their height. Small sharp features that are tall are difficult to develop and this in turn restricts the ability to use sharp, blade-like structures for fine pitch testing. Without sharp, blade-like features, the force required to make good electrical contact will exceed tooling limits.

Turning now to an overview of the aspects of the disclosure, one or more embodiments of the disclosure address the above-described shortcomings of the prior art by providing a wafer test probe and a method of fabricating a wafer test probe. The wafer test probe includes a pillar, a conductive line isolated from and extending through the pillar, a probe tip forming an opening, the opening isolated from the pillar, and a first conductive coating to coat the probe tip at least at the opening. The probe tip includes blade features and a second conductive coating. The blade features are disposed in electrical contact with the conductive line via the first conductive coating. The blade features terminate at the opening and are configured to conductively penetrate a solder bump. The second conductive coating is disposed over the first conductive coating to coat the blade features.

The above-described aspects of the disclosure address the shortcomings of the prior art by providing a wafer test probe that is formed by an etching process to include small, sharp and relatively tall (i.e., high aspect ratio) features for fine pitch testing.

In testing a next-generation System-on-Chip (SoC) for high-performance computing, a semiconductor company can utilize a wafer test probe as described herein, which provides an etched silicon cavity featuring 1 to N blades. These blades can be customized in size to meet various electrical and mechanical needs and are thinly plated with an anti-oxidation material (e.g., NiAu) for reliable connections, electrically isolated by an oxide layer. The etched cavity provides clearance for controlled-collapse chip connection (C4) solder bumps, allowing precise contact with SoC pads, while varying blade lengths accommodate different pad pitches. Accordingly, a wafer test probe according to various non-limiting embodiment described herein can ensure precise, scalable, and cost-effective testing, which are crucial for validating the performance and reliability of complex SoCs.

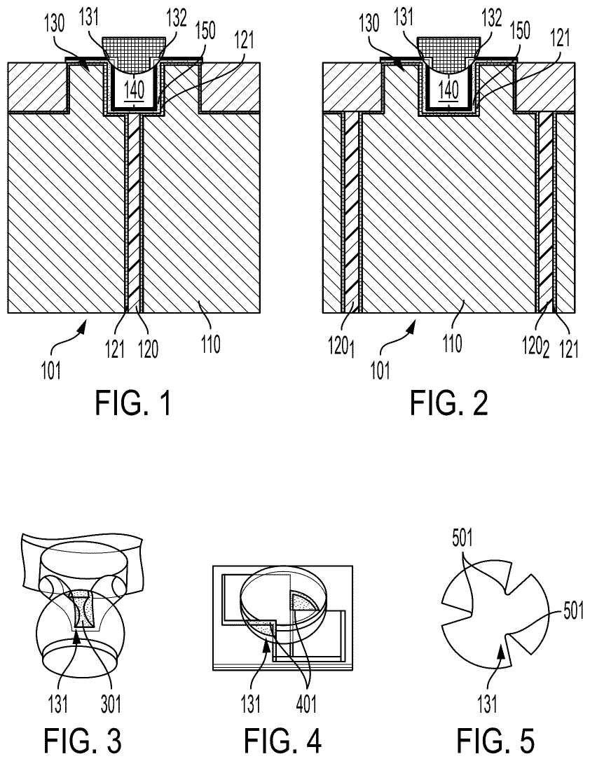

With reference to FIGS. 1 and 2, a wafer test probe 101 is provided and includes a pillar 110 (i.e., of semiconductor material), a conductive line 120 (i.e., a single conductive line 120 as shown in FIG. 1 or first and second conductive lines 120₁ and 120₂ as shown in FIG. 2) isolated from and extending through the pillar 110, a probe tip 130 forming an opening 140 and a first conductive coating 150 to coat the probe tip 130 at least at the opening 140. The conductive line 120 (see FIG. 1) or the first and second conductive lines 120₁ and 120₂ (see FIG. 2) can be provided as a through silicon via (TSV) surrounded by electrically isolating dielectric material 121, such as a passivation layer, especially in cases in which the pillar 110 is formed of semiconductor material. The probe tip 130 includes blade features 131 and a second conductive coating 132. The blade features 131 are electrically isolated from the pillar 110 (i.e., by the electrically isolating dielectric material 121) and are disposed in electrical contact with the conductive line 120 (see FIG. 1) or with the first and second conductive lines 120₁ and 120₂ (see FIG. 2) via the first conductive coating 150. The blade features 131 terminate at the opening 140 and are configured to conductively penetrate a solder bump, such as a controlled-collapse chip connection (C4) solder bump. The second conductive coating 132 is disposed over the first conductive coating to coat the blade features 131.

The opening 140 can be formed by an etching process that allows for C4 clearance and a number of the blade features 131 can be 1 to N. The blade features 131 can have a thin plating of the second conductive coating 132 that is electrically communicative with the conductive line 120 or the first and second conductive lines 120₁ and 120₂ via the first conductive coating 150 and that is electrically isolated from the pillar 110 by the dielectric material 121.

As shown in FIG. 1, the conductive line 120 can be generally aligned with the opening 140. As shown in FIG. 2, the first and second conductive lines 120₁ and 120₂ can be provided on opposite sides of the opening 140.

In accordance with one or more embodiments, the first conductive coating 150 can include a first metallic material, such as nickel or other similar metallic materials, and the second conductive coating 132 can include a second metallic material, which differs from the first metallic material, such as gold or palladium cobalt or other similar metallic materials. In accordance with one or more further embodiments, at least the second conductive coating 132 can be selected for being resistant to oxidation and for being chemically cleanable.

With continued reference to FIGS. 1 and 2 and with additional reference to FIGS. 3-5, the blade features 131 can have various shapes, sizes, dimensions, etc. For example, as shown in FIG. 3, the blade features 131 can have a dog-bone shape 301 that is characterized as being elongate with two opposed concave surfaces by a combination of plating and etching operations. As another example, as shown in FIG. 4, the blade features 131 can be opposed polyhedron tips 401 with sharp interior facing points. As yet another example, as shown in FIG. 5, the blade features 131 can have inward facing blades 501 that are arranged at uniform angular intervals about a central axis.

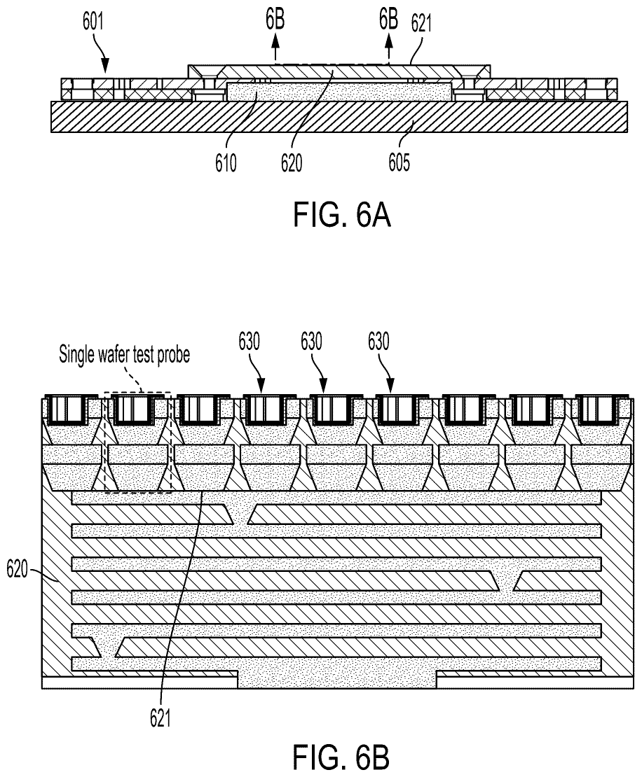

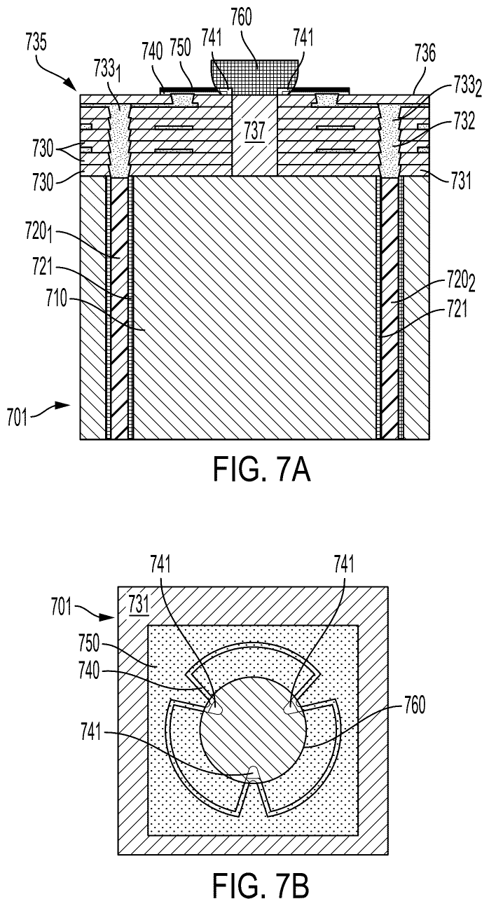

With reference to FIGS. 6A and 6B, a wafer test probe assembly 601 is provided and includes a probe card 605 and a component 620 that can be provided as at least one of a silicon interposer, a fine-pitch organic substrate and a fine-pitch organic substrate with a silicon interposer. The wafer test probe assembly 601 can further include a pogo interposer 610, which is interposed between the probe card 605 and the component 620, and fine-pitch wafer test probes 630. The pogo interposer 610 can be provided as a plurality of spring-like connectors by which the probe card 605 is communicative with the component 620. Each of the fine-pitch wafer test probes 630 can be generally provided in a similar manner as the wafer test probe 101 of FIGS. 1 and 2 (or the wafer test probe 701 of FIGS. 7A and 7B to be described below). As shown in FIG. 6B, the fine-pitch wafer test probes 630 are arranged on a surface 621 of the silicon interposer 620. The silicon interposer can be provided as an integrated stack capacitor (ISC) interposer and can include a plurality of capacitors.

With reference to FIGS. 7A and 7B, a wafer test probe 701 is provided and includes a semiconductor pillar 710, a conductive line 720₁, 720₂ electrically isolated from the semiconductor pillar 710 by dielectric material 721 and extending through the semiconductor pillar 710, layers 730, blade features 740 and a conductive coating 750. The conductive line 720₁, 720₂ can be provided as a single conductive line or as the multiple conductive lines illustrated in FIG. 7A. In any case, the conductive line 720₁, 720₂ can be provided as a TSV. The layers 730 are disposed on an uppermost surface of the semiconductor pillar 710 to form a layer body 735 with an exterior surface 736 and an opening 737. The opening 737 extends into the layer body 735 from the exterior surface 736. Each of the layers 730 can include dielectric material 731 and conductive material 732. The conductive material 732 forms an additional conductive line 733₁, 733₂ that is disposed in electrical contact with the conductive line 720₁, 720₂ and extending through the layer body 735. The blade features 740 are disposed on the exterior surface 736 of the layer body 735 in electrical contact with the additional conductive line 733₁, 733₂. The blade features 740 include terminal ends 741 that terminate at the opening 737 and that are configured to conductively penetrate into a solder bump 760. The blade features 740 can have various shapes, sizes, dimensions, etc., as discussed above with reference to the examples of FIGS. 3-5. The blade features 740 and the terminal ends 741 thereof can include a first metallic material, such as nickel or other similar metallic materials. The conductive coating 750 is disposed on the blade features 740 and the terminal ends 741 thereof. The conductive coating 750 can include a second metallic material, which differs from the first metallic material, such as gold or palladium cobalt or another similar metallic material. The conductive coating 750 can be selected for being resistant to oxidation and for being chemically cleanable.

The opening 737 can be formed by an etching process that allows for C4 clearance and a number of the blade features 740 can be 1 to N. The blade features 740 can have a thin plating of the conductive coating 750 that is disposed in electrical communication with the conductive line 720₁, 720₂ and the additional conductive line 733₁, 733₂ and that is electrically isolated from the semiconductor pillar 710 by the dielectric material 731.

It is to be understood that, while FIG. 7B illustrates the blade features 740 and the terminal ends 741 as having the inward facing structure of the inward facing blades 501 of FIG. 5, this is merely exemplary and that other blade features can be used for the wafer test probe 701.

As noted above, the wafer test probe 701 can be incorporated into a wafer test probe assembly, such as the wafer test probe assembly 601 of FIGS. 6A and 6B.

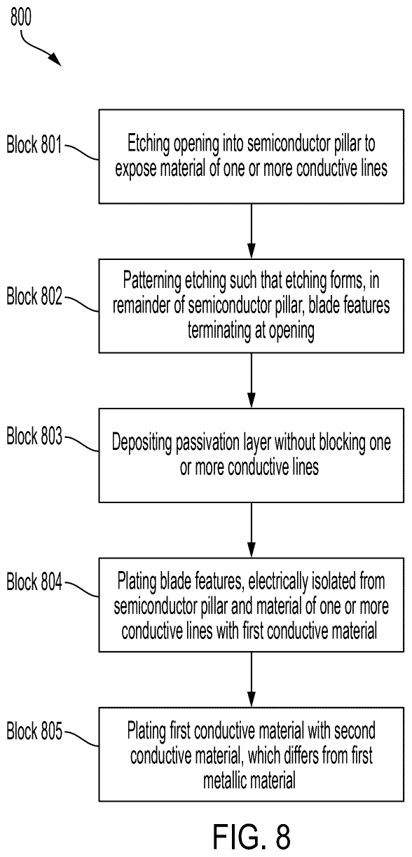

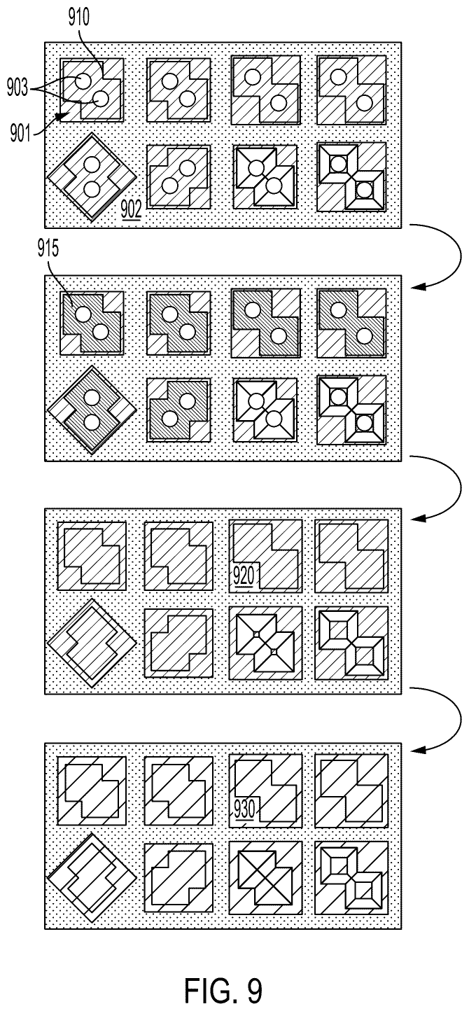

With reference to FIGS. 8 and 9, a method 800 of fabricating a wafer test probe, such as the wafer test probe 101 of FIGS. 1 and 2 and the wafer test probe 701 of FIGS. 7A and 7B, is provided. As shown in FIGS. 8 and 9, the method 800 includes etching an opening 901 into a semiconductor pillar 902 to expose a material 903 of one or more conductive lines by reactive ion etching (RIE), by a wet etching process or by a plasma etching process (block 801 of FIG. 8) and patterning the etching of block 801 such that the etching of block 801 forms, in a remainder of the semiconductor pillar 902, blade features 910 terminating at the opening 901 (block 802 of FIG. 8). The method 800 further includes depositing a passivation layer 915 without blocking the one or more conductive lines (block 803 of FIG. 8) and plating the blade features 910 and the material 903 of the one or more conductive lines with a first conductive material 920, such as nickel or another similar conductive material (block 804 of FIG. 8). In this way, the first conductive material 920 adopts and conforms to the shapes and sizes of the blade features 910 and provides for electrical communication with the material 903 of the one or more conductive lines. Additionally, the method 800 includes plating the first conductive material 920 with a second conductive material 930, which differs from the first metallic material, such as gold or palladium cobalt or another similar metallic material, which resists oxidation and which is chemically cleanable (block 805 of FIG. 8). In this way, the second conductive material 930 adopts and conforms to the shapes and sizes of the blade features 910 along with the first conductive material 920 and provides for electrical communication with the first conductive material 920 and the material 903 of the one or more conductive lines. As such, when a solder ball is pressed against the second conductive material 930, the blade features 910, which are carried through the first conductive material 920 and the second conductive material 930, conductively penetrate the solder ball and an electrical connection is formed from the solder ball to the second conductive material 930, to the first conductive material 920 and to the material 903 of the one or more conductive lines.

In accordance with one or more embodiments, the patterning of block 802 can include for example, one or more of forming the blade features to have a dog-bone shape (see FIG. 3), forming the blade features to be opposed polyhedron tips (see FIG. 4) and forming the blade features to be arranged at uniform angular intervals (see FIG. 5).

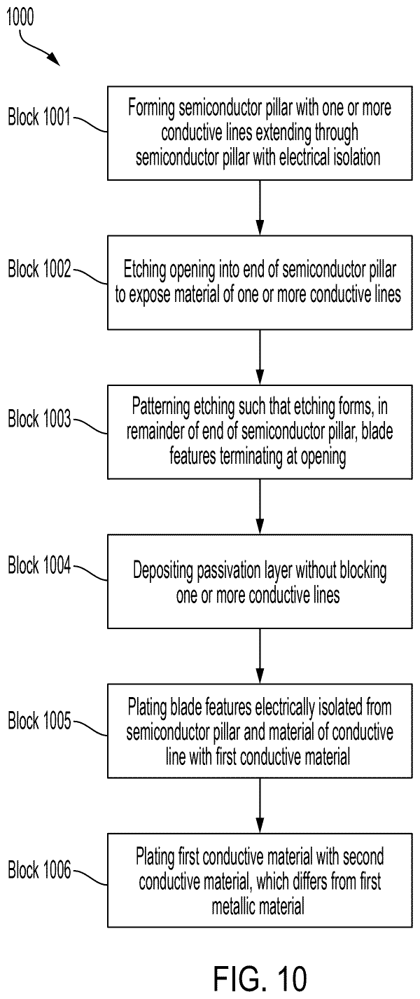

With reference to FIG. 10, a method 1000 of fabricating a wafer test probe, such as the wafer test probe 101 of FIGS. 1 and 2 and the wafer test probe 701 of FIGS. 7A and 7B, is provided. As shown in FIG. 10, the method 1000 includes forming a semiconductor pillar with one or more conductive lines extending through the semiconductor pillar with electrical isolation (block 1001), etching an opening into an end of the semiconductor pillar to expose a material of the one or more conductive lines (block 1002), patterning the etching such that the etching forms, in a remainder of the end of the semiconductor pillar, blade features terminating at the opening (block 1003), depositing a passivation layer without blocking the one or more conductive lines (block 1004), plating the blade features and the material of the conductive line with a first conductive material (block 1005) and plating the first conductive material with a second conductive material, which differs from the first metallic material, which resists oxidation and which is chemically cleanable (block 1006).

In accordance with one or more embodiments, the patterning of block 1003 can include for example, one or more of forming the blade features to have a dog-bone shape (see FIG. 3), forming the blade features to be opposed polyhedron tips (see FIG. 4) and forming the blade features to be arranged at uniform angular intervals (see FIG. 5).

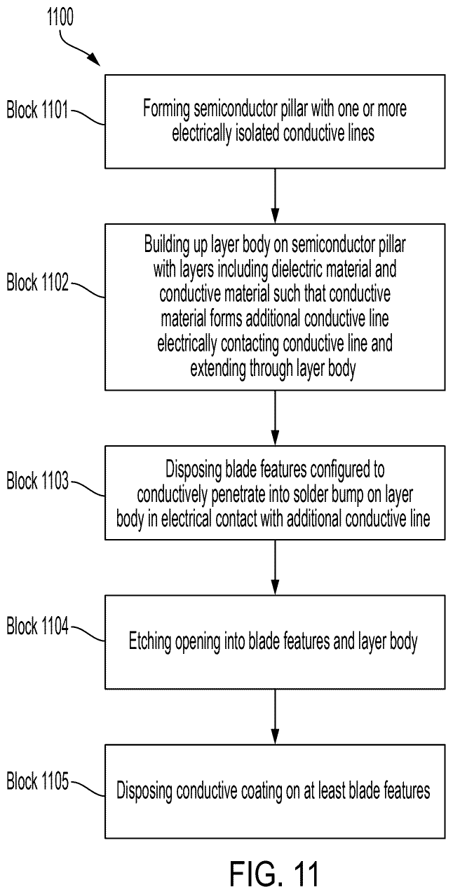

With reference to FIG. 11, a method 1100 of fabricating a wafer test probe, such as the wafer test probe 101 of FIGS. 1 and 2 and the wafer test probe 701 of FIGS. 7A and 7B, is provided. As shown in FIG. 11, the method 1100 includes forming a semiconductor pillar with one or more electrically isolated conductive lines (block 1101), building up a layer body on the semiconductor pillar with layers including dielectric material and conductive material such that the conductive material forms an additional conductive line electrically contacting the conductive line and extending through the layer body (block 1102), disposing blade features configured to conductively penetrate into a solder bump on the layer body in electrical contact with the additional conductive line (block 1103), etching an opening into the blade features and the layer body (block 1104) and disposing a conductive coating on at least the blade features (block 1105).

In accordance with one or more embodiments, the blade features disposed in block 1103 can have, for example, one or more of a dog-bone shape (see FIG. 3), opposed polyhedron tips (see FIG. 4) and blade features arranged at uniform angular intervals (see FIG. 5).

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A wafer test probe, comprising:
a pillar;
a conductive line isolated from and extending through the pillar;
a probe tip forming an opening; and
a first conductive coating isolated from the pillar to coat the probe tip at least at the opening,
the probe tip comprising:
blade features disposed in electrical contact with the conductive line via the first conductive coating, the blade features terminating at the opening and being configured to conductively penetrate a solder bump; and
a second conductive coating disposed over the first conductive coating to coat the blade features.

2. The wafer test probe according to claim 1, wherein the pillar is a semiconductor pillar and the conductive line is a through silicon via (TSV) surrounded by electrically isolating dielectric material.

3. The wafer test probe according to claim 1, wherein the conductive line is provided as first and second conductive lines at opposite sides of the opening.

4. The wafer test probe according to claim 1, wherein:
the first conductive coating comprises a first metallic material, and
the second conductive coating comprises a second metallic material, which differs from the first metallic material, which resists oxidation and which is chemically cleanable.

5. The wafer test probe according to claim 1, wherein the blade features have a dog-bone shape.

6. The wafer test probe according to claim 1, wherein the blade features are opposed polyhedron tips.

7. The wafer test probe according to claim 1, wherein the blade features are inward blades arranged at uniform angular intervals.

8. A wafer test probe assembly, comprising:
a probe card;
at least one of a silicon interposer, a fine-pitch organic substrate and a fine-pitch organic substrate with a silicon interposer;
a pogo interposer interposed between the probe card and the at least one of the silicon interposer, the fine-pitch organic substrate and the fine-pitch organic substrate with the silicon interposer; and
fine-pitch wafer test probes according to the wafer test probe of claim 1 arranged on a surface of the at least one of the silicon interposer, the fine-pitch organic substrate and the fine-pitch organic substrate with the silicon interposer.

9. A wafer test probe, comprising:
a semiconductor pillar;
a conductive line isolated from and extending through the semiconductor pillar;
layers disposed on the semiconductor pillar to form a layer body with an exterior surface and an opening extending into the layer body from the exterior surface, each of the layers comprising dielectric material and conductive material, the conductive material forming an additional conductive line in electrical contact with the conductive line and extending through the layer body;
blade features disposed on the exterior surface of the layer body in electrical contact with the additional conductive line, the blade features comprising terminal ends that terminate at the opening and that are configured to conductively penetrate into a solder bump; and
a conductive coating disposed on the blade features and the terminal ends thereof.

10. The wafer test probe according to claim 9, wherein the conductive line is a through silicon via (TSV) surrounded by electrically isolating dielectric material.

11. The wafer test probe according to claim 9, wherein the conductive line is provided as first and second conductive lines at opposite sides of the opening.

12. The wafer test probe according to claim 9, wherein:
the blade features comprise a first metallic material, and
the conductive coating comprises a second metallic material, which differs from the first metallic material, which resists oxidation and which is chemically cleanable.

13. The wafer test probe according to claim 9, wherein the blade features have a dog-bone shape.

14. The wafer test probe according to claim 9, wherein the blade features are opposed polyhedron tips.

15. The wafer test probe according to claim 9, wherein the blade features are inward blades arranged at uniform angular intervals.

16. A wafer test probe assembly, comprising:
a probe card;
a silicon interposer disposed on the probe card; and
fine-pitch wafer test probes according to the wafer test probe of claim 9 arranged on a surface of the silicon interposer.

17. A method of fabricating a wafer test probe, the method comprising:
etching an opening into a semiconductor pillar to expose a material of one or more conductive lines electrically isolated from the semiconductor pillar;
patterning the etching such that the etching forms, in a remainder of the semiconductor pillar, blade features electrically isolated from the semiconductor pillar and terminating at the opening;
plating the blade features and the material of the one or more conductive lines with a first conductive material; and
plating the first conductive material with a second conductive material, which differs from the first metallic material, which resists oxidation and which is chemically cleanable.

18. The method according to claim 17, wherein the patterning comprises forming the blade features to have a dog-bone shape.

19. The method according to claim 17, wherein the patterning comprises forming the blade features to be opposed polyhedron tips.

20. The method according to claim 17, wherein the patterning comprises forming the blade features to be arranged at uniform angular intervals.

21. A method of fabricating a wafer test probe, the method comprising:
forming a semiconductor pillar with one or more conductive lines extending through the semiconductor pillar with electrical isolation;
etching an opening into an end of the semiconductor pillar to expose a material of the one or more conductive lines;
patterning the etching such that the etching forms, in a remainder of the end of the semiconductor pillar, blade features electrically isolated from the semiconductor pillar and terminating at the opening;
plating the blade features and the material of the conductive line with a first conductive material; and
plating the first conductive material with a second conductive material, which differs from the first metallic material, which resists oxidation and which is chemically cleanable.

22. The method according to claim 21, wherein the patterning comprises forming the blade features to have a dog-bone shape.

23. The method according to claim 21, wherein the patterning comprises forming the blade features to be opposed polyhedron tips.

24. The method according to claim 21, wherein the patterning comprises forming the blade features to be arranged at uniform angular intervals.

25. A method of fabricating a wafer test probe, the method comprising:
forming a semiconductor pillar with one or more electrically isolated conductive lines;
building up a layer body on the semiconductor pillar with layers comprising dielectric material and conductive material such that the conductive material forms an additional conductive line electrically contacting the conductive line and extending through the layer body;
disposing blade features configured to conductively penetrate into a solder bump on the layer body in electrical contact with the additional conductive line;
etching an opening into the blade features and the layer body; and
disposing a conductive coating on at least the blade features.
